(19) United States
(12) Patent Application Publication
(10) Pub. No.: US 2023/0076418 A1
(43) Pub. Date: Mar. 9, 2023

(54) THERMAL MANAGEMENT SYSTEM FOR A VEHICLE UTILIZING A MULTI-PORT VALVE ASSEMBLY

(71) Applicant: Rivian IP Holdings, LLC, Plymouth, MI (US)

(72) Inventors: Jing He, Novi, MI (US); Henry Huang, Ann Arbor, MI (US); David John Revolinski, Dana Point, CA (US)

(21) Appl. No.: 17/466,014

(22) Filed: Sep. 3, 2021

(51) Int. Cl. B60K 11/02; G05D 7/06; B60L 58/26; B60L 53/20; B60K 1/04; H05K 7/20

(52) U.S. Cl. CPC B60K 11/02; B60K 1/04; B60L 53/20; B60L 58/26; G05D 7/0635; H05K 7/20881; B60K 2001/006

(57) ABSTRACT

A thermal management system and method for a vehicle, including: a heat-cold source thermal management circuit; an energy storage system thermal management circuit; a power electronics thermal management circuit; and a multi-port valve assembly coupled to the heat-cold source thermal management circuit, the energy storage system thermal management circuit, and the power electronics thermal management circuit and adapted to, responsive to an operating state of the vehicle, selectively couple and isolate the heat-cold source thermal management circuit, the energy storage system thermal management circuit, and the power electronics thermal management circuit to and from one another.

### INTRODUCTION

The present disclosure relates generally to the automotive field. More particularly, the present disclosure relates to a thermal management system (TMS) for a vehicle, such as an electric vehicle (EV) or a hybrid electric vehicle (HEV), utilizing a multi-port valve assembly that selectively interconnects the heat-cold source (HCS) thermal management loop, the energy storage system (ESS) thermal management loop, and the power electronics (PE) thermal management loop of the vehicle.

Cabin climate control, the management of an ESS (i.e., a battery or battery pack), and the cooling of PE in EVs and HEVs can pose challenges under certain operating conditions. In particular, it is desirable to manage heat transfer among a vehicle cabin, ESS, and PE in a holistic manner for energy efficiency and appropriate load distribution, as well as to meet increasing demands on ESS cooling, especially during direct current (DC) fast charging, off-road operation, and/or towing operation. Further, it is desirable to alleviate cell-to-cell temperature variations within a battery pack to ensure optimal performance and battery life. Further, it is desirable to recover waste heat from an ESS or PE for energy efficiency and real world range improvement.

The present background is provided as illustrative environmental context only and should not be construed as being limiting in any manner. The principles of the present disclosure may be applied in other environmental contexts equally.

### SUMMARY

The present disclosure provides an TMS to manage energy transfer in a more efficient and holistic manner among the cabin, ESS, and PE of a vehicle, thereby enabling cost competitive and comprehensive modes to handle varied operating conditions and the effective use of a heat pump. The TMS of the present disclosure utilizes a multi-port valve assembly, such as a six-port valve assembly with three inlets and three outlets or two four-port valve assemblies each with two inlets and two outlets, to selectively interconnect the cabin thermal management loop, the ESS thermal management loop, and the PE thermal management loop of a vehicle.

The TMS of the present disclosure utilizes a multi-port valve assembly, such as a six-port valve assembly, to establish a thermal architecture that selectively interconnects the heat-cold source (HCS) circuit of a vehicle, including at least a heat source and a cold source, for example, with the ESS circuit of the vehicle (representing the ESS thermal management loop), including a battery or battery pack, with the powertrain (PWT) circuit of the vehicle (representing the PE thermal management loop), including PE such as an onboard charger (OBC), a DC-to-DC (DCDC) converter, an inverter, and an electric motor (EM), for example. The multi-port valve assembly is configured to selectively isolate or interconnect these three circuits, providing a highly integrated, cost competitive, and energy efficient scheme for thermal management. By way of example, this scheme enables reversible flow across the ESS to enhance cell-to-cell thermal uniformity, the recovery of waste heat from the ESS and/or PE, when available, and fast warm-up during cold ambient conditions, due to possible combined heating from both the heat source and EM. The result includes enhanced battery performance and life, improve DC fast charging rate, and improved real world driving range.

In one illustrative embodiment, the present disclosure provides a thermal management system for a vehicle, including: a cabin thermal management loop; an energy storage system thermal management loop; a power electronics thermal management loop; and a multi-port valve assembly coupled to the cabin thermal management loop, the energy storage system thermal management loop, and the power electronics thermal management loop and adapted to, responsive to an operating state of the vehicle, selectively isolate and couple the cabin thermal management loop, the energy storage system thermal management loop, and the power electronics thermal management loop from and to one another.

In another illustrative embodiment, the present disclosure provides a thermal management method for a vehicle, including: responsive to an operating state of the vehicle, selectively isolating and coupling a cabin thermal management loop of the vehicle, an energy storage system thermal management loop of the vehicle, and a power electronics thermal management loop of the vehicle from and to one another using a multi-port valve assembly coupled to the cabin thermal management loop, the energy storage system thermal management loop, and the power electronics thermal management loop.

In a further exemplary embodiment, the present disclosure provides a non-transitory computer readable medium stored in a memory and executed by a processor to carry out thermal management method steps, including: responsive to an operating state of a vehicle, selectively isolating and coupling a cabin thermal management loop of the vehicle, an energy storage system thermal management loop of the vehicle, and a power electronics thermal management loop of the vehicle from and to one another using a multi-port valve assembly coupled to the cabin thermal management loop, the energy storage system thermal management loop, and the power electronics thermal management loop.

Responsive to the operating state of the vehicle, the multi-port valve assembly is operated in one of the following modes: a first mode isolating the cabin thermal management loop, the energy storage system thermal management loop, and the power electronics thermal management loop from one another; a second mode isolating the cabin thermal management loop and coupling the energy storage system thermal management loop and the power electronics thermal management loop to one another; a third mode coupling the cabin thermal management loop and the energy storage system thermal management loop to one another and isolating the power electronics thermal management loop; a fourth mode coupling the cabin thermal management loop, the energy storage system thermal management loop, and the power electronics thermal management loop to one another; and a fifth mode (which is a specific embodiment of the fourth mode) coupling the cabin thermal management loop, the energy storage system thermal management loop, and the power electronics thermal management loop to one another, wherein the energy storage system thermal management loop includes a chiller, the cabin thermal management loop includes a water-cooled condenser, and the thermal management system is part of a heat pump system.

In a further exemplary embodiment, the present disclosure provides a thermal management system for a vehicle, including: a heat-cold source thermal management circuit; an energy storage system thermal management circuit; a powertrain thermal management circuit; and a multi-port valve assembly coupled to the heat-cold source thermal management circuit, the energy storage system thermal management circuit, and the power electronics thermal management circuit and adapted to, responsive to an operating state of the vehicle, selectively couple or isolate the heat-cold source thermal management circuit, the energy storage system thermal management circuit, and the powertrain thermal management circuit to or from one another. The multi-port valve assembly includes a six-port valve assembly including three inlet ports and three outlet ports.

In a further exemplary embodiment, the present disclosure provides a thermal management method for a vehicle, including: responsive to an operating state of the vehicle, selectively coupling or isolating a heat-cold source thermal management circuit of the vehicle, an energy storage system thermal management circuit of the vehicle, and a powertrain thermal management circuit of the vehicle to or from one another using a multi-port valve assembly coupled to the heat-cold source thermal management circuit, the energy storage system thermal management circuit, and the powertrain thermal management circuit. The multi-port valve assembly includes a single six-port valve assembly including three inlet ports and three outlet ports.

In a further exemplary embodiment, the present disclosure provides a non-transitory computer readable medium stored in a memory and executed by a processor to carry out thermal management method steps, including: responsive to an operating state of the vehicle, selectively coupling or isolating a heat-cold source thermal management circuit of the vehicle, an energy storage system thermal management circuit of the vehicle, and a powertrain thermal management circuit of the vehicle to or from one another using a multi-port valve assembly coupled to the heat-cold source thermal management circuit, the energy storage system thermal management circuit, and the powertrain thermal management circuit. The multi-port valve assembly includes a single six-port valve assembly including three inlet ports and three outlet ports.

Responsive to the operating state of the vehicle, the multi-port valve assembly is operated in one of the following modes: a first mode coupling the heat-cold source thermal management circuit to the energy storage system thermal management circuit and isolating the powertrain thermal management circuit from the heat-cold source thermal management circuit and the energy storage system thermal management circuit; a second mode cross-coupling the heat-cold source thermal management circuit to the energy storage system thermal management circuit (with a relative flow direction reversal) and isolating the powertrain thermal management circuit from the heat-cold source thermal management circuit and the energy storage system thermal management circuit; a third mode isolating the heat-cold source thermal management circuit, the energy storage system thermal management circuit, and the powertrain thermal management circuit from one another; a fourth mode coupling the heat-cold source thermal management circuit to the powertrain thermal management circuit and isolating the energy storage system thermal management circuit from the heat-cold source thermal management circuit and the powertrain thermal management circuit; and a fifth mode coupling the heat-cold source thermal management circuit, the energy storage system thermal management circuit, and the powertrain thermal management circuit to one another.

### BRIEF DESCRIPTION OF THE DRAWINGS

The present disclosure is illustrated and described herein with reference to the various drawings, in which like reference numbers are used to denote like system components/method steps, as appropriate, and in which:

FIG. 1 is a schematic diagram of one illustrative embodiment of the TMS of the present disclosure, utilizing a six-port valve assembly with three inlets and three outlets;

FIG. 2 is a series of schematic diagrams of various modes of operation of the six-port valve assembly with three inlets and three outlets of FIG. 1;

FIG. 3 is a schematic diagram of another illustrative embodiment of the TMS of the present disclosure, utilizing two four-port valve assemblies each with two inlets and two outlets;

FIG. 4 is a series of schematic diagrams of various modes of operation of the two four-port valve assemblies each with two inlets and two outlets of FIG. 3;

FIG. 5 is a schematic diagram illustrating an isolation mode of operation of the TMS of the present disclosure;

FIG. 6 is a schematic diagram illustrating an ESS/power electronics interconnection mode of operation of the TMS of the present disclosure;

FIG. 7 is a schematic diagram illustrating a cabin/ESS interconnection mode of operation of the TMS of the present disclosure;

FIG. 8 is a schematic diagram illustrating a cabin/ESS/power electronics interconnection mode of operation of the TMS of the present disclosure;

FIG. 9 is a schematic diagram illustrating one embodiment of the cabin/ESS/power electronics interconnection mode of operation of the TMS of the present disclosure;

FIG. 10 is a thermodynamic diagram of pressure versus enthalpy associated with the embodiment of the cabin/ESS/power electronics interconnection mode of operation of FIG. 9;

FIG. 11 is a schematic diagram of one illustrative embodiment of the power electronics circuit of the present disclosure;

FIG. 12 is a schematic diagram of another illustrative embodiment of the power electronics circuit of the present disclosure;

FIG. 13 is a block diagram of a control system that may be used in conjunction with the TMS of the present disclosure;

FIG. 14 is a schematic diagram of another illustrative embodiment of the TMS of the present disclosure, utilizing a six-port valve assembly with three inlets and three outlets;

FIG. 15 is a schematic diagram illustrating the components of the HCS thermal management circuit utilized in conjunction with the TMS of FIG. 14;

FIG. 16 is a schematic diagram illustrating the components of the ESS thermal management circuit utilized in conjunction with the TMS of FIG. 14;

FIG. 17 is a schematic diagram illustrating the components of the PWT thermal management circuit utilized in conjunction with the TMS of FIG. 14;

FIG. 18 is a schematic diagram illustrating a first operating mode of the TMS of FIG. 14 with the HCS thermal management circuit of FIG. 15 coupled to the ESS thermal management circuit of FIG. 16 and the PWT thermal management circuit of FIG. 17 isolated from both;

FIG. 19 is a schematic diagram illustrating a second operating mode of the TMS of FIG. 14 with the HCS thermal management circuit of FIG. 15 coupled to the ESS thermal management circuit of FIG. 16 in a reverse configuration and the PWT thermal management circuit of FIG. 17 isolated from both;

FIG. 20 is a schematic diagram illustrating a cooling plate of an ESS experiencing a hot zone that can be alleviated when the TMS of FIG. 14 is alternating between the first mode of FIG. 18 and the second mode of FIG. 19;

FIG. 21 is a schematic diagram illustrating a third operating mode of the TMS of FIG. 14 with the HCS thermal management circuit of FIG. 15 isolated from the ESS thermal management circuit of FIG. 16 and the PWT thermal management circuit of FIG. 17 isolated from both;

FIG. 22 is a schematic diagram illustrating a fourth operating mode of the TMS of FIG. 14 with the HCS thermal management circuit of FIG. 15 coupled to the PWT thermal management circuit of FIG. 17 and isolated from the ESS thermal management circuit of FIG. 16; and

FIG. 23 is a schematic diagram illustrating a fifth operating mode of the TMS of FIG. 14 with the HCS thermal management circuit of FIG. 15 coupled to the ESS thermal management circuit of FIG. 16 and coupled to the PWT thermal management circuit of FIG. 17.

### DETAILED DESCRIPTION

Cabin climate control, the management of an ESS (i.e., a battery or battery pack), and the cooling of PE in EVs and HEVs can pose challenges under certain operating conditions, e.g., battery charging in extremely cold ambient conditions (below -20° C.), or during off-road or towing operation where PE can become hot and require high-load cooling. With the rapid advance in the electrification of vehicles, an TMS is desired to manage energy transfer among the cabin, ESS, and PE in a holistic manner for enhanced efficiency and capability.

The present disclosure provides an TMS to manage energy transfer in a more efficient and holistic manner among the cabin, ESS, and PE, thereby enabling cost competitive and comprehensive modes to handle varied operating conditions and effective use of a heat pump. The TMS of the present disclosure utilizes a multi-port valve assembly, such as a six-port valve assembly with three inlets and three outlets or two four-port valve assemblies each with two inlets and two outlets, to selectively interconnect a cabin thermal management loop, an ESS thermal management loop, and a PE loop.

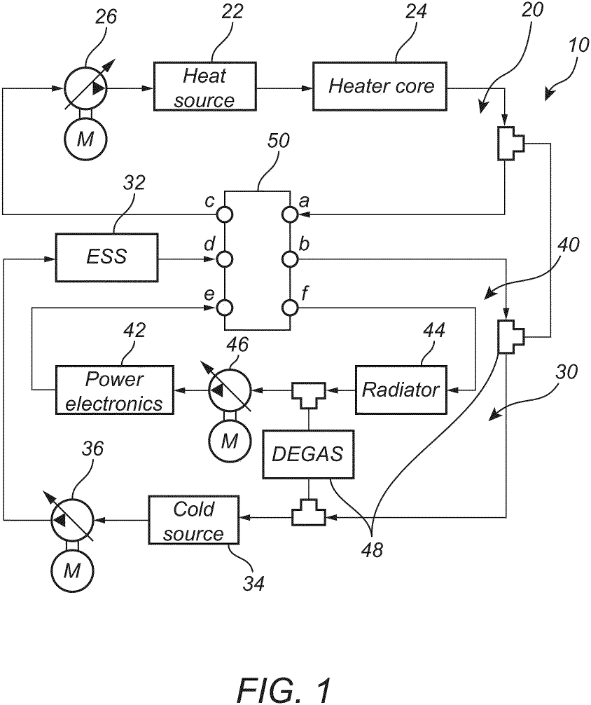

Referring now specifically to FIG. 1, in one illustrative embodiment, the TMS 10 of the present disclosure includes three selectively interconnected thermal management loops: a cabin thermal management loop 20, an ESS thermal management loop 30, and a PE loop 40. These thermal management loops are selectively interconnected by a multi-port valve assembly 50, which here includes a six-port valve assembly with three inlets, a, d, and e, and three outlets, c, b, and f.

The cabin thermal management loop 20 generally includes a heating assembly such as a heat source 22, which may include a coolant heater, a water-cooled condenser, a hot thermal storage unit, or a combination of two or more of the aforementioned sources, and a heating assembly such as a heat exchanger 24, which may include a heater core, conventionally associated with an internal combustion engine (ICE). A pump assembly 26 is also provided. Collectively, the heat source 22, the heat exchanger 24, and the pump assembly 26 are operable for controlling the environment associated with the cabin of a vehicle.

The ESS thermal management loop 30 generally includes the ESS 32, such as a battery or battery pack, and a cold source 34, such as a chiller or cold thermal storage unit. A pump assembly 36 is also provided. Collectively, the ESS 32, the cold source 34, and the pump assembly 36 are operable for controlling the environment associated with the ESS 32.

The PE thermal management loop 40 generally includes the PE 42, such as motors, inverters/converters, sensors, control systems, and other interface electronics, and a radiator 44, conventionally associated with an ICE. A pump assembly 46 is also provided. Collectively, the PE 42, the radiator 44, and the pump assembly 46 are operable for controlling the environment associated with the PE 42. A degas assembly 48 includes a degas bottle and associated hoses and tee junctions that provide coolant storage and a deaeration function among the cabin thermal management loop 20, the ESS thermal management loop 30, and the PE thermal management loop 40.

Again, these thermal management loops are selectively interconnected by the multi-port valve assembly 50, which here includes a six-port valve assembly with three inlets, a, d, and e, and three outlets, c, b, and f. These inlets and outlets are selectively enabled/disabled, either by mechanical or electronic means, such as by software, firmware, and/or hardware means.

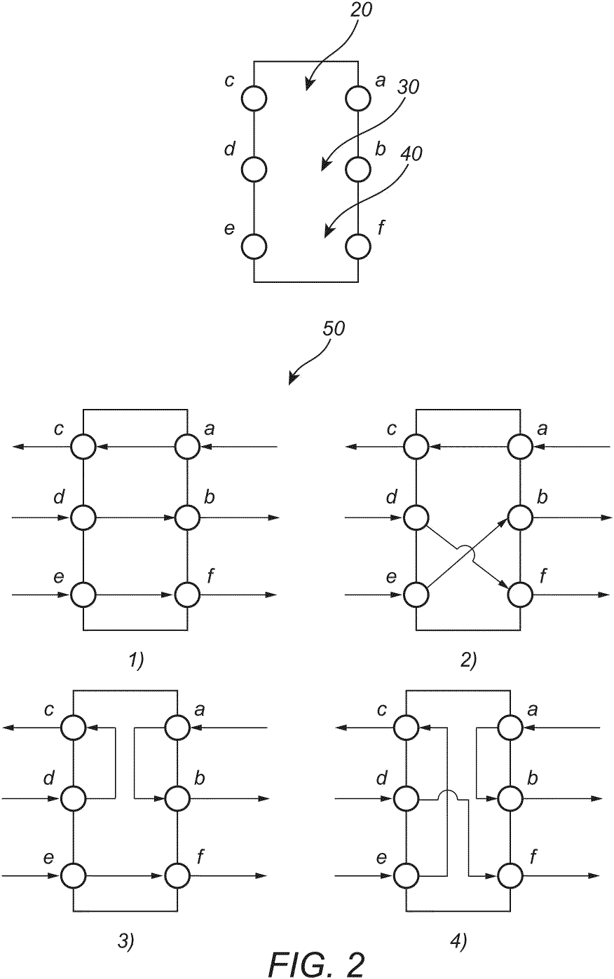

Referring now specifically to FIGS. 1 and 2, in one illustrative embodiment, the six-port valve assembly 50 with three inlets and three outlets includes the cabin thermal management loop 20 generally coupled between inlet a and outlet c, the ESS thermal management loop 30 generally coupled between inlet d and outlet b, and the PE thermal management loop 40 generally coupled between inlet e and outlet f. These inlets and outlet connections could, of course, be varied, and are by selective operation of the six-port valve assembly 50. In operation mode 1 illustrated, the three thermal management loops are all isolated from one another, with the cabin thermal management loop 20 still coupled between inlet a and outlet c, the ESS thermal management loop 30 still coupled between inlet d and outlet b, and the PE thermal management loop 40 coupled between inlet e and outlet f. In operation mode 2 illustrated, the cabin thermal management loop 20 is still isolated from the ESS thermal management loop 30 and the PE thermal management loop 40, but the ESS thermal management loop 30 and the PE thermal management loop 40 are now interconnected, with the cabin thermal management loop 20 still coupled between inlet a and outlet c, the ESS thermal management loop 30 now coupled between inlet d and outlet f, and the PE thermal management loop 40 now coupled between inlet e and outlet b. In operation mode 3 illustrated, the PE thermal management loop 40 is still isolated from the cabin thermal management loop 20 and the ESS thermal management loop 30, but the cabin thermal management loop 20 and the ESS thermal management loop 30 are now interconnected, with the cabin thermal management loop 20 now coupled between inlet a and outlet b, the ESS thermal management loop 30 now coupled between inlet d and outlet c, and the PE thermal management loop 40 still coupled between inlet e and outlet f. In operation mode 4 illustrated, the cabin thermal management loop 20, the ESS thermal management loop 30, and the PE thermal management loop 40 are now all interconnected, with the cabin thermal management loop 20 now coupled between inlet a and outlet b, the ESS thermal management loop 30 now coupled between inlet d and outlet f, and the PE thermal management loop 40 now coupled between inlet e and outlet c. Other operation modes are, of course, also possible.

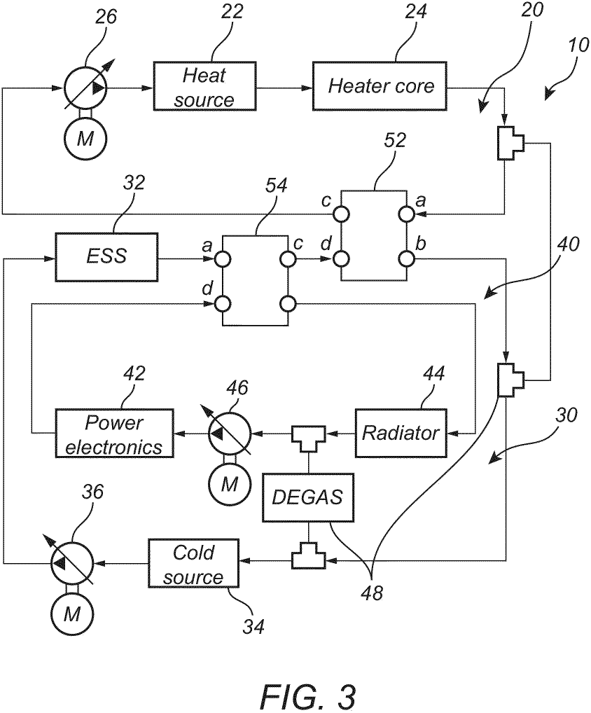

Referring now specifically to FIG. 3, in another illustrative embodiment, the TMS 10 of the present disclosure again includes three selectively interconnected thermal management loops: a cabin thermal management loop 20, an ESS thermal management loop 30, and a PE loop 40. These thermal management loops are selectively interconnected by multiple multi-port valve assemblies 52,54, which here each include a four-port valve assembly with two inlets, a and d, and two outlets, c and b.

Again, the cabin thermal management loop 20 generally includes heating assembly such as a heat source 22, which may include a coolant heater, a water-cooled condenser, a hot thermal storage unit, or a combination of two or more of the aforementioned sources, and a heating assembly such as a heat exchanger 24, which may include a heater core, conventionally associated with an ICE. A pump assembly 26 is also provided. Collectively, the heat source 22, the heat exchanger 24, and the pump assembly 26 are operable for controlling the environment associated with the cabin of a vehicle.

The ESS thermal management loop 30 generally includes the ESS 32, such as a battery or battery pack, and a cold source 34, such as a chiller or cold thermal storage unit. A pump assembly 36 is also provided. Collectively, the ESS 32, the cold source 34, and the pump assembly 36 are operable for controlling the environment associated with the ESS 32.

The PE thermal management loop 40 generally includes the PE 42, such as motors, inverters/converters, sensors, control systems, and other interface electronics, and a radiator 44, conventionally associated with an ICE. A pump assembly 46 is also provided. Collectively, the PE 42, the radiator 44, and the pump assembly 46 are operable for controlling the environment associated with the PE 42. A degas assembly 48 includes a degas bottle and associated hoses and tee junctions that provide coolant storage and a deaeration function among the cabin thermal management loop 20, the ESS thermal management loop 30, and the PE thermal management loop 40.

Again, these thermal management loops are selectively interconnected by the multiple multi-port valve assemblies 52,54, which here include two four-port valve assemblies each with two inlets, a and d, and two outlets, c and b. These inlets and outlets are selectively enabled/disabled, either by mechanical or electronic means, such as by software, firmware, and/or hardware means. As illustrated, one four-port valve assembly 52 selectively interconnects the cabin thermal management loop 20 with the ESS thermal management loop 30, while the other four-port valve assembly 54 selectively interconnects the ESS thermal management loop 30 with the PE thermal management loop 40, thereby selectively interconnecting all three thermal management loops through the two four-port valve assemblies 52,54 linked in series.

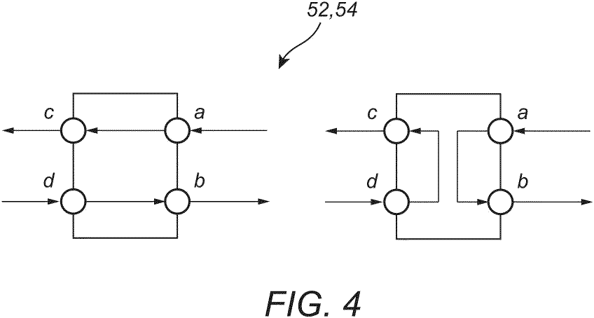

Referring now specifically to FIGS. 3 and 4, in another illustrative embodiment, one of the four-port valve assemblies 52 with two inlets and two outlets includes the cabin thermal management loop 20 generally coupled between inlet a and outlet c and the ESS thermal management loop 30 generally coupled between inlet d and outlet b. These inlets and outlet connections could, of course, be varied, and are by selective operation of the four-port valve assembly 52. The other of the four-port valve assemblies 54 with two inlets and two outlets includes the ESS thermal management loop 30 generally coupled between inlet a and outlet c and the PE thermal management loop 40 generally coupled between inlet d and outlet b. These inlets and outlet connections could also, of course, be varied, and are by selective operation of the four-port valve assembly 54. The two valve assemblies 52,54 are coupled via inlet d of the first valve assembly 52 and outlet c of the second valve assembly 54, in the illustrative embodiment provided. In operation, the inlet and outlet ports of both valve assemblies 52,54 can be variably cross-connected to interconnect the various thermal management loops 20,30,40. As illustrated in FIG. 4, by way of example only, inlet a can be coupled to outlet b, while inlet d can be coupled to outlet c.

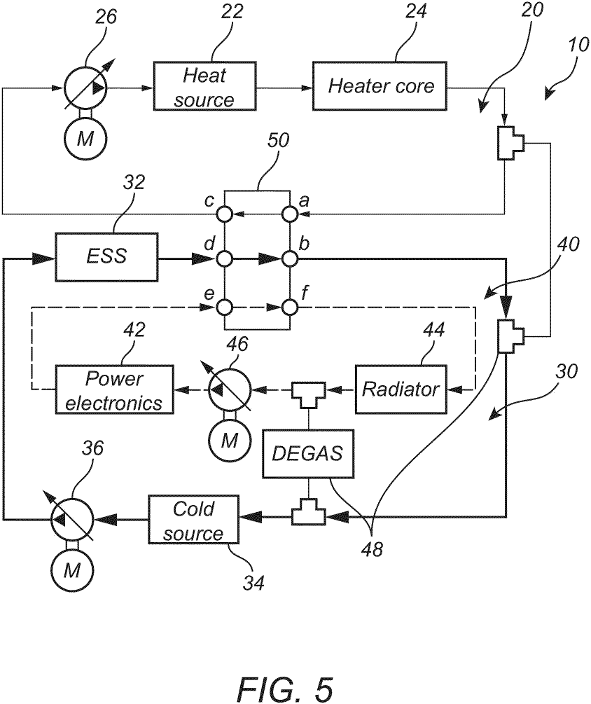

Referring now specifically to FIG. 5, in an isolation mode of operation of the TMS 10, each of the cabin thermal management loop 20, the ESS thermal management loop 30, and the PE thermal management loop 40 are isolated from one another via appropriate actuation of the multi-port valve assembly 50, which prohibits interconnection. Here, in the vehicle, the cabin heating may be on or off, by turning on or off the heat source 22 and pump assembly 26, depending upon the occupant heating request. The ESS 32 is in either a self-circulation mode for temperature equalization, with the cold source 34 off, or in an active cooling mode, with the cold source 34 on. The PE 42 are cooled by the radiator 44.

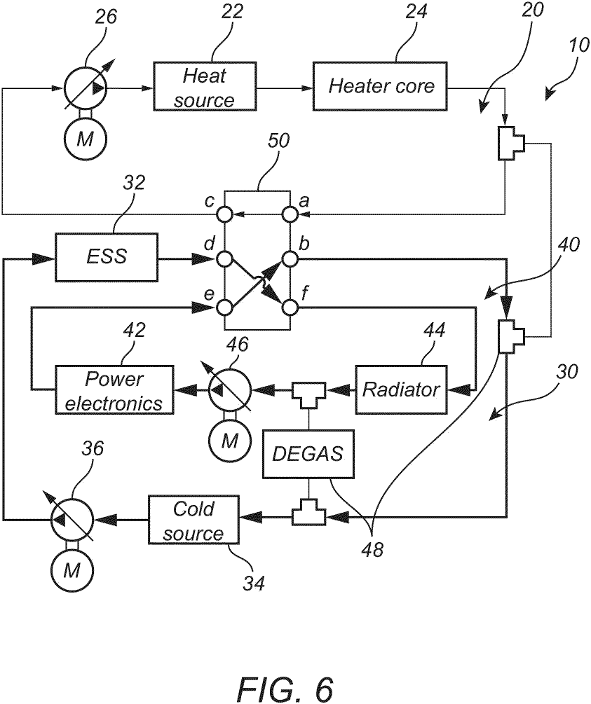

Referring now specifically to FIG. 6, in an ESS/PE interconnection mode of operation of the TMS 10, the ESS thermal management loop 30 and the PE thermal management loop 40 are interconnected with one another, but isolated from the cabin thermal management loop 20, via appropriate actuation of the multi-port valve assembly 50, which selectively prohibits interconnection. Here, in the vehicle, the cabin heating may be on or off, by turning on or off the heat source 22 and pump assembly 26, depending upon the occupant heating request. The ESS 32 and the PE may be cooled by the radiator 44, with the active grille shutter (AGS) open, or waste heat may be recovered from the ESS 32 and the PE 42 via the cold source 34, with the AGS closed, depending upon the mode of operation.

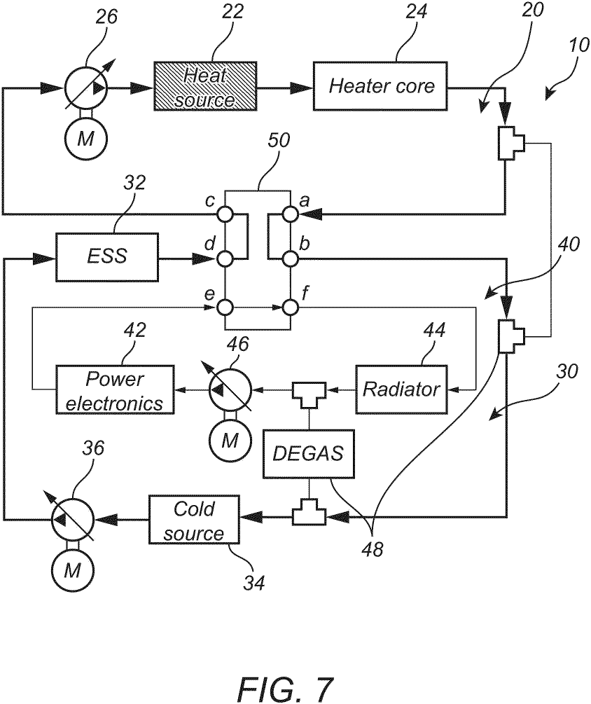

Referring now specifically to FIG. 7, in a cabin/ESS interconnection mode of operation of the TMS 10, the cabin thermal management loop 20 and the ESS thermal management loop 30 are interconnected with one another, but isolated from the PE thermal management loop 40, via appropriate actuation of the multi-port valve assembly 50, which selectively prohibits interconnection. This mode may be activated for preconditioning of the ESS 32 alone, or for preconditioning of the both the cabin and the ESS 32, utilizing heat from the heat source 22.

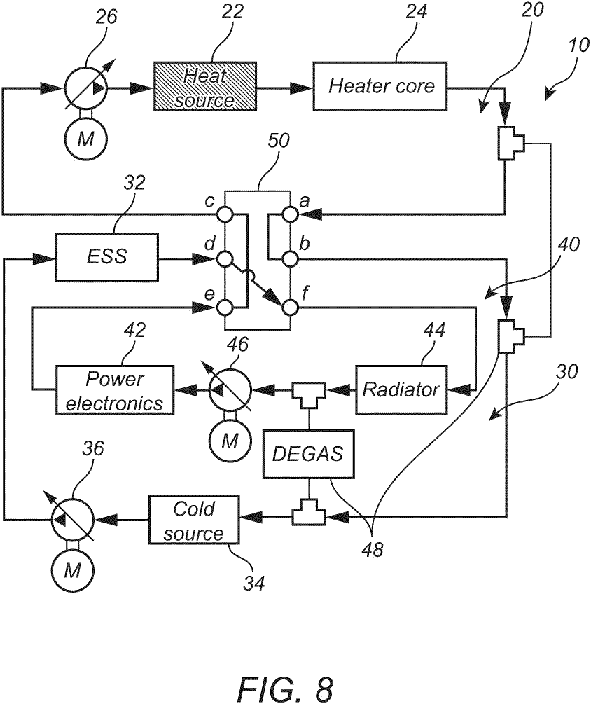

Referring now specifically to FIG. 8, in a cabin/ESS/PE interconnection mode of operation of the TMS 10, the cabin thermal management loop 20, the ESS thermal management loop 30, and the PE thermal management loop 40 are interconnected with one another via appropriate actuation of the multi-port valve assembly 50, which selectively enables interconnection. This mode may be activated for preconditioning of the ESS 32 alone, or for preconditioning of the both the cabin and the ESS 32, now utilizing heat from the heat source 22 plus possibly waste heat from the PE 42.

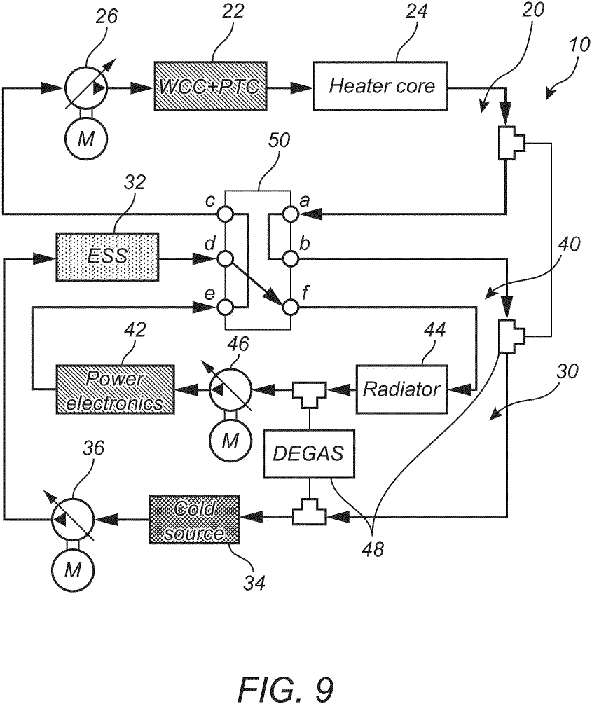

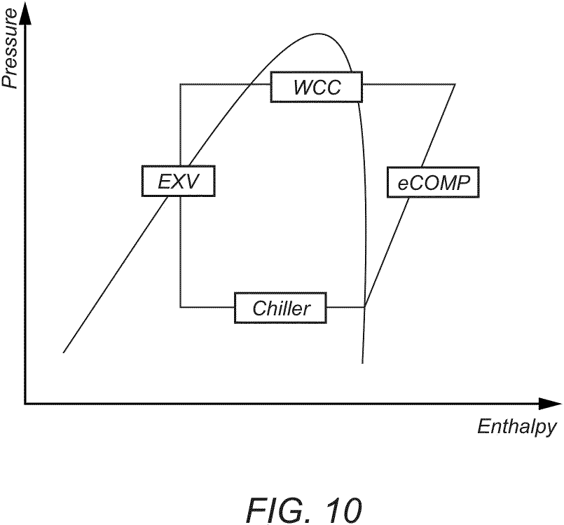

Referring now specifically to FIG. 9, in one embodiment of the cabin/ESS/PE interconnection mode of operation of the TMS 10, the cabin thermal management loop 20, the ESS thermal management loop 30, and the PE thermal management loop 40 are again interconnected with one another via appropriate actuation of the multi-port valve assembly 50, which selectively enables interconnection. Here, the cold source 34 includes at least a chiller, the hot source 22 includes at least a water-cooled condenser (WCC) and a positive temperature coefficient (PTC) electrical heater, and the TMS 10 is part of a heat pump system (note, the refrigerant side is omitted for simplicity). The low-grade heat from the PE 42 is absorbed via the chiller 34, converted into a high-grade heat via compressor work, and rejected via WCC to the coolant circuit. The refrigerant cycle is illustrated in the thermodynamic diagram of pressure versus enthalpy in FIG. 10. As this process continues, the coolant temperature rises, the refrigerant-side pressure in the chiller elevates, and the compressor power input increases, which in turn yields more heat output in WCC. The heating capacity therefore increases exponentially. The PTC heater and/or PE may be engaged to further increase the heating capacity. This mode is particularly useful for max heat load conditions, for example cold startup of EVs below -20 degree C, to reduce battery and/or cabin preconditioning time and improve charging rate.

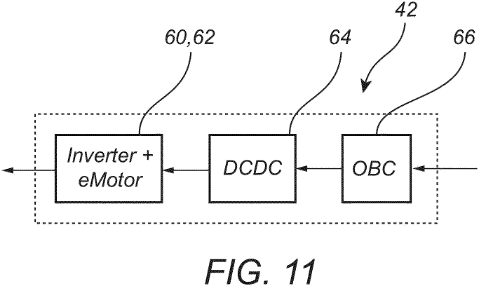

FIG. 11 is a schematic diagram of one illustrative embodiment of the PE circuit 42 of the present disclosure. Here, the PE circuit 42 includes an inverter 60 and traction motor 62 coupled to a DCDC converter 64 coupled to an OBC 66.

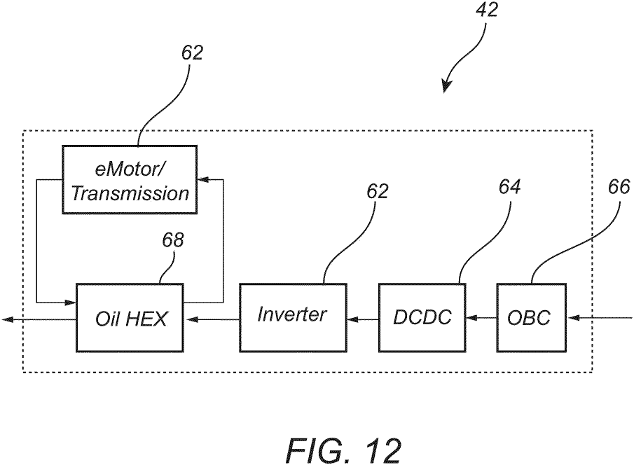

FIG. 12 is a schematic diagram of another illustrative embodiment of the PE circuit 42 of the present disclosure. Here, the PE circuit 42 includes a separate inverter 60 and traction motor/transmission 62 coupled to the DC/DC converter 64 coupled to the OBC 66. The inverter 60 and motor/transmission 62 are each coupled to an oil heat exchanger 68.

It is to be recognized that, depending on the example, certain acts or events of any of the techniques described herein can be performed in a different sequence, may be added, merged, or left out altogether (e.g., not all described acts or events are necessary for the practice of the techniques). Moreover, in certain examples, acts or events may be performed concurrently, e.g., through multi-threaded processing, interrupt processing, or multiple processors, rather than sequentially.

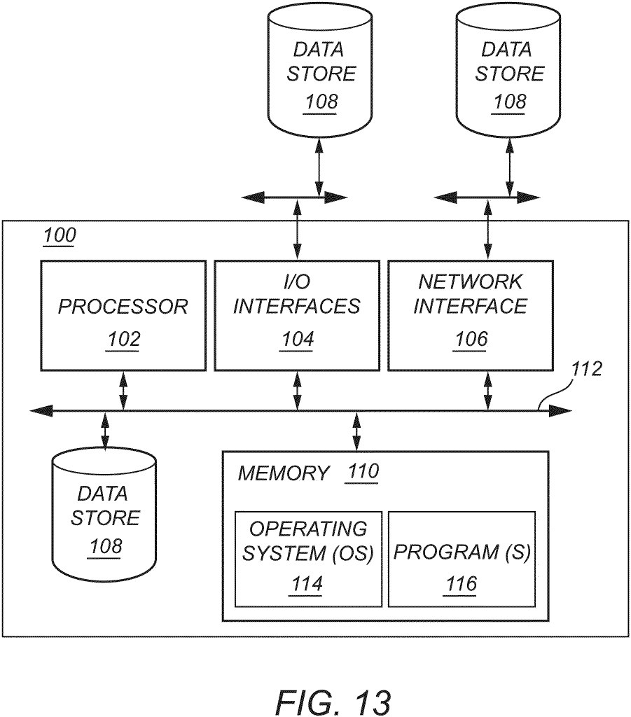

FIG. 13 illustrates a control system 100 that may be used to direct operation of the TMS and valve assembly or assemblies of the present disclosure, including a processor 102. The processor 102 is a hardware device for executing software instructions embodied in a non-transitory computer-readable medium. The processor 102 may be any custom made or commercially available processor, a central processing unit (CPU), an auxiliary processor among several processors associated with a server, a semiconductor-based microprocessor (in the form of a microchip or chipset), or generally any device for executing software instructions. When the control system 100 is in operation, the processor 102 is configured to execute software stored within the memory 110, to communicate data to and from the memory 110, and to generally control operations of the control system 100 pursuant to the software instructions. I/O interfaces 104 may be used to receive user input from and/or for providing system output to one or more devices or components.

A network interface 106 may be used to enable the control system 100 to communicate on a network, such as the Internet or a Local Area Network (LAN). The network interface 106 may include, for example, an Ethernet card or adapter (e.g., 10BaseT, Fast Ethernet, Gigabit Ethernet, or 10GbE) or a Wireless Local Area Network (WLAN) card or adapter (e.g., 802.11a/b/g/n/ac). The network interface 106 may include address, control, and/or data connections to enable appropriate communications on the network. A data store 108 may be used to store data. The data store 108 may include any of volatile memory elements (e.g., random access memory (RAM, such as DRAM, SRAM, SDRAM, and the like)), nonvolatile memory elements (e.g., ROM, hard drive, tape, CDROM, and the like), and combinations thereof. Moreover, the data store 108 may incorporate electronic, magnetic, optical, and/or other types of storage media. In one example, the data store 108 may be located internal to the control system 100, such as, for example, an internal hard drive connected to the local interface 112 in the control system 100. Additionally, in another embodiment, the data store 108 may be located external to the control system 100 such as, for example, an external hard drive connected to the I/O interfaces 104 (e.g., a SCSI or USB connection). In a further embodiment, the data store 108 may be connected to the control system 100 through a network, such as, for example, a network-attached file server.

The memory 110 may include any of volatile memory elements (e.g., random access memory (RAM, such as DRAM, SRAM, SDRAM, etc.)), nonvolatile memory elements (e.g., ROM, hard drive, tape, CDROM, etc.), and combinations thereof. Moreover, the memory 110 may incorporate electronic, magnetic, optical, and/or other types of storage media. Note that the memory 110 may have a distributed architecture, where various components are situated remotely from one another but can be accessed by the processor 102. The software in memory 110 may include one or more software programs, each of which includes an ordered listing of executable instructions for implementing logical functions. The software in the memory 110 includes a suitable operating system (O/S) 114 and one or more programs 116. The operating system 114 essentially controls the execution of other computer programs, such as the one or more programs 116, and provides scheduling, input-output control, file and data management, memory management, and communication control and related services. The one or more programs 116 may be configured to implement the various processes, algorithms, methods, techniques, etc. described herein.

It will be appreciated that some embodiments described herein may include one or more generic or specialized processors (“one or more processors”) such as microprocessors; central processing units (CPUs); digital signal processors (DSPs); customized processors such as network processors (NPs) or network processing units (NPUs), graphics processing units (GPUs), or the like; field programmable gate arrays (FPGAs); and the like along with unique stored program instructions (including both software and firmware) for control thereof to implement, in conjunction with certain non-processor circuits, some, most, or all of the functions of the methods and/or systems described herein. Alternatively, some or all functions may be implemented by a state machine that has no stored program instructions, or in one or more application-specific integrated circuits (ASICs), in which each function or some combinations of certain of the functions are implemented as custom logic or circuitry. Of course, a combination of the aforementioned approaches may be used. For some of the embodiments described herein, a corresponding device in hardware and optionally with software, firmware, and a combination thereof can be referred to as “circuitry configured or adapted to,” “logic configured or adapted to,” etc. perform a set of operations, steps, methods, processes, algorithms, functions, techniques, etc. on digital and/or analog signals as described herein for the various embodiments.

Moreover, some embodiments may include a non-transitory computer-readable storage medium having computer-readable code stored thereon for programming a computer, server, appliance, device, processor, circuit, etc. each of which may include a processor to perform functions as described and claimed herein. Examples of such computer-readable storage mediums include, but are not limited to, a hard disk, an optical storage device, a magnetic storage device, a Read-Only Memory (ROM), a Programmable Read-Only Memory (PROM), an Erasable Programmable Read-Only Memory (EPROM), an Electrically Erasable Programmable Read-Only Memory (EEPROM), flash memory, and the like. When stored in the non-transitory computer-readable medium, software can include instructions executable by a processor or device (e.g., any type of programmable circuitry or logic) that, in response to such execution, cause a processor or the device to perform a set of operations, steps, methods, processes, algorithms, functions, techniques, etc. as described herein for the various embodiments.

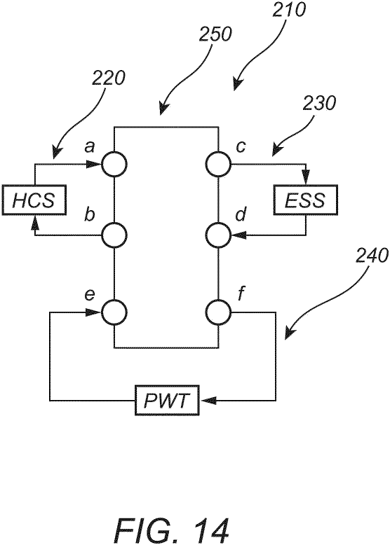

Referring now specifically to FIG. 14, in another illustrative embodiment, the TMS 210 of the present disclosure includes the three selectively interconnected thermal management loops: the HCS thermal management circuit 220 (i.e., the heat-cold source thermal management loop), the ESS thermal management circuit 230 (i.e., the ESS thermal management loop), and the PWT thermal management circuit 240 (i.e., the PE thermal management loop). These thermal management circuits 220, 230, and 240 are selectively interconnected by the multi-port valve assembly 250, which here includes a valve assembly with six ports, a through f. In the present embodiment, a and e are inlet ports, b and f are outlet ports, while c and d can be either inlet or outlet ports. In general, integration is the trend in EV thermal management, where, in vehicles with a heater core instead of a HVAC cabin condenser, the cold source, or chiller, is part of the heat-cold source (HCS) loop, as opposed to the ESS loop described above. This enables different modes of operation, as described below.

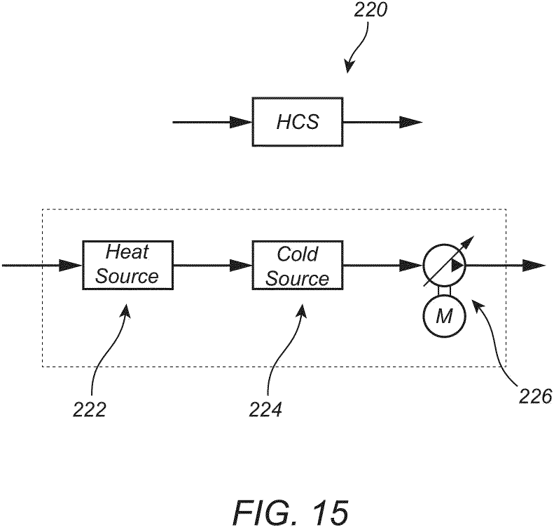

Referring now specifically to FIG. 15, the HCS thermal management circuit 220 generally includes a heat source 222, which may include a coolant heater, a water-cooled condenser, a hot thermal storage unit, or a combination of two or more of the aforementioned sources, and a cold source 224, which may include a chiller, a cold thermal storage unit, or a combination of both. A pump assembly 226 is also provided. Collectively, the heat source 222, the cold source 224, and the pump assembly 226 are operable for controlling the environment associated with the HCS thermal management circuit 220.

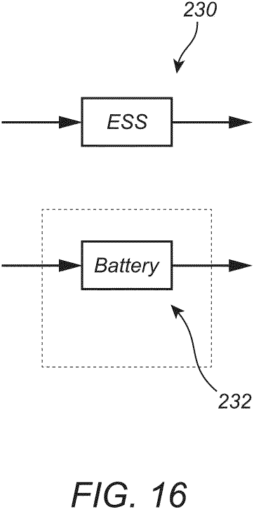

Referring now specifically to FIG. 16, the ESS thermal management circuit 230 generally includes the ESS 232, such as a battery or battery pack, and optionally a cold source such as a chiller or cold thermal storage unit. A pump assembly may also be optionally provided. The ESS thermal management circuit 230 is operable for controlling the environment associated with the ESS 232.

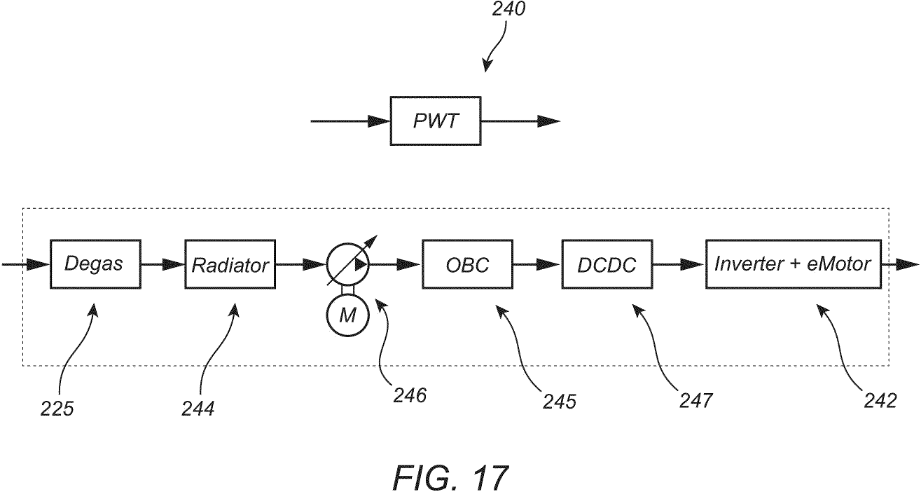

Referring now specifically to FIG. 17, the PWT thermal management circuit 240 generally includes the electric motor 242 such as motors, inverters/converters, sensors, control systems, and other interface electronics, a degas bottle 225 that provides coolant storage and deaeration function, and a radiator 244 that dissipates heat to the ambient air. A pump assembly 246 is also provided. The PWT thermal management circuit 240 further includes an OBC 245 and a DCDC converter 247. Collectively, the electric motor 242, the degas bottle 225, the radiator 244, the pump assembly 246, the OBC 245, and the DCDC converter 247 are operable for controlling the environment associated with the PWT thermal management circuit 240.

Again, these thermal management loops are selectively interconnected by the multi-port valve assembly 250, which here is a valve assembly with six ports, a through f. In the present embodiment, a and e are inlet ports, b and f are outlet ports, while c and d can be either inlet or outlet ports. These inlets and outlets are selectively enabled/disabled, either by mechanical or electronic means, such as by software, firmware, and/or hardware means.

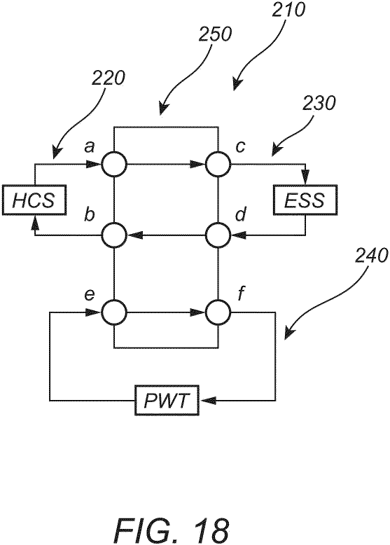

FIG. 18 is a schematic diagram illustrating a first operating mode of the TMS 210 with the HCS thermal management circuit 220 coupled to the ESS thermal management circuit 230 and the PWT thermal management circuit 240 isolated from both. Specifically, the HCS thermal management circuit 220 utilizes outlet port b and inlet port a of the multi-port valve assembly 250 coupled to inlet port d and outlet port c of the ESS thermal management circuit 230, respectively. The PWT thermal management circuit 240 still utilizes outlet port f and inlet port e across the multi-port valve assembly 250. This setup may provide active ESS 232 (FIG. 16) cooling by the cold source 224 (FIG. 15) of the HCS thermal management circuit 220, when the cold source 224, e.g. a chiller, is ON. When the cold source 224 is OFF, ESS coolant self-circulation is provided for temperature equalization. This setup may also provide ESS 232 heating (FIG. 16) by the heat source 222 (FIG. 15) of the HCS thermal management circuit 220, when the heat source 222 is ON. This setup enables waste heat recovery from the ESS thermal management circuit 230, where heat rejection from the ESS 232 (FIG. 16) is absorbed by the cold source 224 (FIG. 15). The electric motor 242, OBC 245, and DCDC 247 (FIG. 17) are cooled by the radiator 244 (FIG. 17).

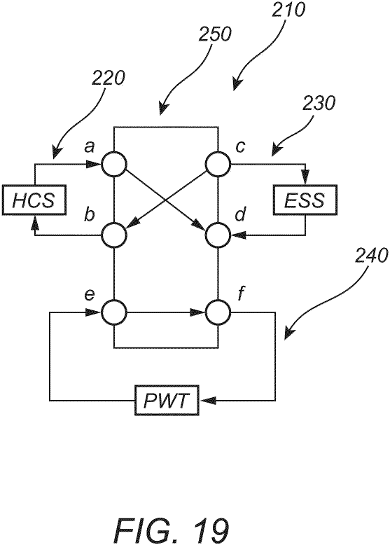

FIG. 19 is a schematic diagram illustrating a second operating mode of the TMS 210 with the HCS thermal management circuit 220 coupled to the ESS thermal management circuit 230 in a reverse configuration and the PWT thermal management circuit 240 isolated from both. Specifically, the HCS thermal management circuit 220 utilizes outlet port b and inlet port a of the multi-port valve assembly 250 coupled to inlet port c and outlet port d of the ESS thermal management circuit 230, respectively, thereby effectively reversing the flow through the ESS thermal management circuit 230. The PWT thermal management circuit 240 still utilizes outlet port f and inlet port e across the multi-port valve assembly 250. This setup again may provide active ESS 232 (FIG. 16) cooling by the cold source 224 (FIG. 15) of the HCS thermal management circuit 220, when the cold source 224, e.g. a chiller, is ON. When the cold source 224 is OFF, ESS coolant self-circulation is provided for temperature equalization. This setup may again provide ESS 232 heating by the heat source 222 (FIG. 15) of the HCS thermal management circuit 220, when the heat source 222 is ON. This setup again enables waste heat recovery from the ESS thermal management circuit 230, where heat rejection from the ESS 232 (FIG. 16) is absorbed by the cold source 224 (FIG. 15). The electric motor 242, OBC 245, and DCDC 247 (FIG. 17) are cooled by the radiator 244 (FIG. 17), as is conventional.

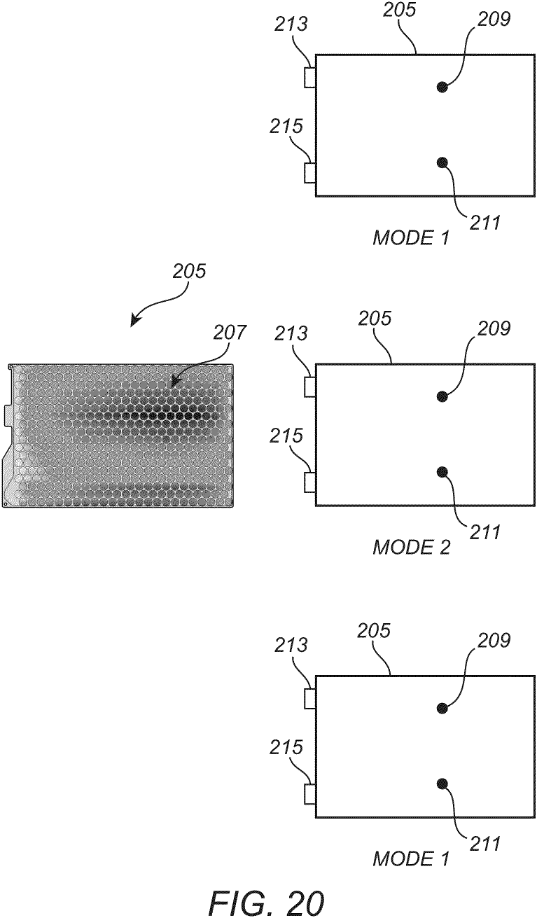

FIG. 20 illustrates a cooling plate 205 of the ESS 232 experiencing a hot zone 207, representing cell-to-cell temperature variations. Temperature nonuniformity within a battery pack may adversely affect battery performance and charging rate. Using temperature sensors within the ESS 232, an effective cooling strategy could be alternating the flow direction periodically by switching the multi-port valve assembly 250 between the first mode of FIG. 18 and the second mode of FIG. 19. In some examples, the multi-port valve assembly 250 may be switched in response to a predetermined degree of thermal nonuniformity being detected, e.g., when the temperature difference between two temperature sensors disposed in or on the cooling pate 205 exceeds a predetermined threshold. Reverse in the coolant flow direction is expected to alleviate cell-to-cell temperature variations by both introducing fresh, cold coolant from alternating inlets and by further mixing or agitating the coolant within the cooling plate 205. In FIG. 20, a first coolant port 213 and a second coolant port 215 are shown, as well as a first temperature sensor 209 in a first area of the cooling plate 205 and a second temperature sensor 211 in a second area of the cooling plate 205. The measurement of the temperature differential between the first temperature sensor 209 and the second temperature sensor 211 represents the cell-to-cell temperature variation across the cooling plate 205. As illustrated in this operation modality, beginning in the first operating mode (MODE 1), port 213 acts as the outlet and port 215 acts as the inlet. The temperature sensor 211 reading is lower than the temperature sensor 209 reading, as the second area of the cooling plate receives fresh, cold coolant. The temperature variation (sensor 209 reading minus sensor 211 reading) increases until exceeding a predetermined threshold, when the system switches to the second operating mode (MODE 2). The first port 213 now acts as the inlet and the second port 215 now acts as the outlet. Eventually, the temperature sensor 209 reading is lower than the temperature sensor 211 reading, as the first area of the cooling plate 205 now receives fresh, cold coolant. The temperature variation between sensor 209 and sensor 211 then increases until exceeding the predetermined threshold, when the system switches back to MODE 1, thereby alternating between MODE 1 and MODE 2 to balance cooling of the cooling pate 205 and associated cells. Alternating may not be needed if the temperature differential between the two sensors 209 and 211 is always less than the predetermined threshold.

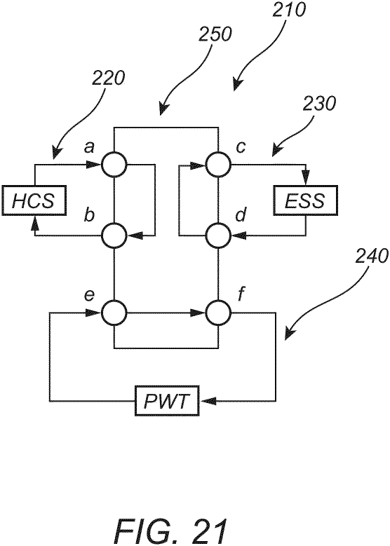

FIG. 21 is a schematic diagram illustrating a third operating mode of the TMS 210 with the HCS thermal management circuit 220 isolated from the ESS thermal management circuit 230 and the PWT thermal management circuit 240 isolated from both. Specifically, the HCS thermal management circuit 220 utilizes outlet port b and inlet port a of the multi-port valve assembly 250. The ESS thermal management circuit 230 utilizes outlet port c and inlet port d of the multi-port valve assembly 250. Finally, the PWT thermal management circuit 240 utilizes outlet port f and inlet port e of the multi-port valve assembly 250. No cross-connections are made across the multi-port valve assembly 250. This setup may provide complete circuit isolation, with the cold source 224 (FIG. 15) heated by the heat source 222 (FIG. 15) to facilitate cabin heating by bypassing the heavy thermal mass of the ESS 232 (FIG. 16). This mode is particularly useful for fast warmup in winter temperatures (<0 degree C), if cabin comfort is prioritized over battery heating, which occurs, for example, when the battery temperature is acceptable (>10° C.).

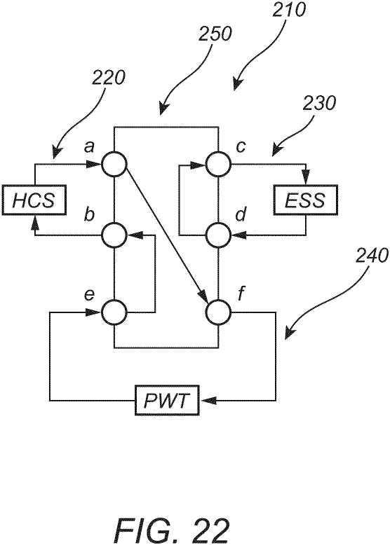

FIG. 22 is a schematic diagram illustrating a fourth operating mode of the TMS 210 with the HCS thermal management circuit 220 isolated from the ESS thermal management circuit 230 but coupled to the PWT thermal management circuit 240. Specifically, the HCS thermal management circuit 220 utilizes outlet port b and inlet port a of the multi-port valve assembly 250. The ESS thermal management circuit 230 utilizes outlet port c and inlet port d of the multi-port valve assembly 250. Finally, the PWT thermal management circuit 240 utilizes outlet port f and inlet port e of the multi-port valve assembly 250. Inlet port a is cross-connected to outlet port f, while inlet port e is cross-connected to outlet port b, thereby connecting the HCS thermal management circuit 220 and the PWT thermal management circuit 240 across the multi-port valve assembly 250. This setup may provide active cooling of the PWT thermal management circuit 240 (FIG. 17) using the cold source 224 (FIG. 15), if needed, or active heating of the PWT thermal management circuit 240 (FIG. 17) using the heat source 222, if needed, such as during a cold startup. This setup enables waste heat recovery from the PWT thermal management circuit 240, where heat rejection from the electric motor 242, OBC 245, and DCDC 247 (FIG. 17) is absorbed directly by the cold source 224 (FIG. 15), bypassing the ESS 232 (FIG. 16) when its temperature is not high. Comparing to the third operating mode of the TMS 210 (FIG. 21), this setup may provide even faster warmup in winter temperatures (<0 degree C), with added heat from the electric motor 242 by deliberately running the motor inefficiently.

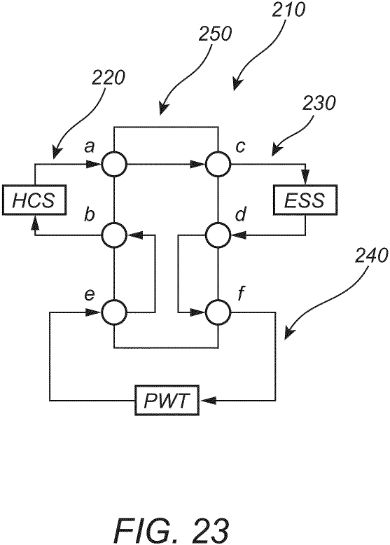

FIG. 23 is a schematic diagram illustrating a fifth operating mode of the TMS 210 with the HCS thermal management circuit 220 coupled to the ESS thermal management circuit 230 and coupled to the PWT thermal management circuit 240. Specifically, the HCS thermal management circuit 220 utilizes outlet port b and inlet port a of the multi-port valve assembly 250. The ESS thermal management circuit 230 utilizes outlet port c and inlet port d of the multi-port valve assembly 250. Finally, the PWT thermal management circuit 240 utilizes outlet port f and inlet port e of the multi-port valve assembly 250. Inlet port a is cross-connected to outlet port c across the multi-port valve assembly 250, while inlet port d is connected to outlet port f, while inlet port e is connected to outlet port b. This setup may provide universal circuit interconnection, allowing waste heat recovery from both the ESS thermal management circuit 230 and the PWT thermal management circuit 240. In extreme environments, with ambient temperatures below -30° C. and fully soaked battery pack, this setup may provide effective heating of the ESS 232, with combined heating from both the heat source 222 (FIG. 15) of the HCS thermal management circuit 220 and the electric motor 242 of the PWT thermal management circuit 240 (by deliberately running the motor inefficiently). This setup may also provide active cooling for both the ESS thermal management circuit 230 and the PWT thermal management circuit 240, via the cold source 224 (FIG. 15).

Although the present disclosure is illustrated and described with reference to illustrative embodiments and examples thereof, it will be readily apparent to those of ordinary skill in the art that other embodiments and examples may perform similar functions and/or achieve like results. All such equivalent embodiments and examples are within the spirit and scope of the present disclosure, are contemplated thereby, and are intended to be covered by the following non-limiting claims for all purposes.

What is claimed is:

1. A thermal management system for a vehicle, comprising:
a heat-cold source thermal management circuit;
an energy storage system thermal management circuit;
a powertrain thermal management circuit; and
a multi-port valve assembly coupled to the heat-cold source thermal management circuit, the energy storage system thermal management circuit, and the power electronics thermal management circuit and adapted to, responsive to an operating state of the vehicle, selectively couple or isolate the heat-cold source thermal management circuit, the energy storage system thermal management circuit, and the powertrain thermal management circuit to or from one another.

2. The thermal management system of claim 1, wherein the heat-cold source thermal management circuit comprises a heat source, a cold source, or a pump, or a combination thereof, adapted to affect a temperature associated with the heat-cold source thermal management circuit.

3. The thermal management system of claim 1, wherein the energy storage system thermal management circuit comprises an energy storage system.

4. The thermal management system of claim 1, wherein the powertrain thermal management circuit comprises power electronics, a degas bottle, a radiator, an on-board charger, a direct current-to-direct current converter, or a pump, or a combination thereof, and wherein the power electronics comprise an inverter or a motor, or a combination thereof.

5. The thermal management system of claim 1, wherein the multi-port valve assembly comprises a six-port valve assembly comprising three inlet ports and three outlet ports.

6. The thermal management system of claim 1, wherein, responsive to the operating state of the vehicle, the multi-port valve assembly is operated in one of the following modes:
a first mode coupling the heat-cold source thermal management circuit to the energy storage system thermal management circuit and isolating the powertrain thermal management circuit from the heat-cold source thermal management circuit and the energy storage system thermal management circuit;
a second mode cross-coupling the heat-cold source thermal management circuit to the energy storage system thermal management circuit and isolating the powertrain thermal management circuit from the heat-cold source thermal management circuit and the energy storage system thermal management circuit;
a third mode isolating the heat-cold source thermal management circuit, the energy storage system thermal management circuit, and the powertrain thermal management circuit from one another;
a fourth mode coupling the heat-cold source thermal management circuit to the powertrain thermal management circuit and isolating the energy storage system thermal management circuit from the heat-cold source thermal management circuit and the powertrain thermal management circuit; and
a fifth mode coupling the heat-cold source thermal management circuit, the energy storage system thermal management circuit, and the powertrain thermal management circuit to one another.

7. The thermal management system of claim 1, wherein, responsive to exceeding a predetermined threshold measured temperature differential between a first temperature sensor disposed at a first location of a cooling plate of the energy storage system thermal management circuit and a second temperature sensor disposed at a second location of the cooling plate of the energy storage system thermal management circuit, the multi-port valve assembly is switched between the following modes:
a first mode coupling the heat-cold source thermal management circuit to the energy storage system thermal management circuit with a first cooling plate port serving as an inlet and a second cooling plate port serving as an outlet; and
a second mode cross-coupling the heat-cold source thermal management circuit to the energy storage system thermal management circuit with the second cooling plate port serving as the inlet and the first cooling plate port serving as the outlet.

8. A thermal management method for a vehicle, comprising:
responsive to an operating state of the vehicle, selectively coupling or isolating a heat-cold source thermal management circuit of the vehicle, an energy storage system thermal management circuit of the vehicle, and a powertrain thermal management circuit of the vehicle to or from one another using a multi-port valve assembly coupled to the heat-cold source thermal management circuit, the energy storage system thermal management circuit, and the powertrain thermal management circuit.

9. The thermal management method of claim 8, wherein the heat-cold source thermal management circuit comprises a heat source, a cold source, or a pump, or a combination thereof, adapted to affect a temperature within the heat-cold source thermal management circuit.

10. The thermal management method of claim 8, wherein the energy storage system thermal management circuit comprises an energy storage system.

11. The thermal management method of claim 8, wherein the powertrain thermal management circuit comprises power electronics, a degas bottle, a radiator, an on-board charger, a direct current-to-direct current converter, or a pump, or a combination thereof, and wherein the power electronics comprise an inverter and a motor, or a combination thereof.

12. The thermal management method of claim 8, wherein the multi-port valve assembly comprises a single six-port valve assembly comprising three inlet ports and three outlet ports.

13. The thermal management method of claim 8, wherein, responsive to the operating state of the vehicle, the multi-port valve assembly is operated in one of the following modes:
a first mode coupling the heat-cold source thermal management circuit to the energy storage system thermal management circuit and isolating the powertrain thermal management circuit from the heat-cold source thermal management circuit and the energy storage system thermal management circuit;
a second mode cross-coupling the heat-cold source thermal management circuit to the energy storage system thermal management circuit and isolating the powertrain thermal management circuit from the heat-cold source thermal management circuit and the energy storage system thermal management circuit;
a third mode isolating the heat-cold source thermal management circuit, the energy storage system thermal management circuit, and the powertrain thermal management circuit from one another;
a fourth mode coupling the heat-cold source thermal management circuit to the powertrain thermal management circuit and isolating the energy storage system thermal management circuit from the heat-cold source thermal management circuit and the powertrain thermal management circuit; and
a fifth mode coupling the heat-cold source thermal management circuit, the energy storage system thermal management circuit, and the powertrain thermal management circuit to one another.

14. The thermal management method of claim 8, wherein, responsive to exceeding a predetermined threshold measured temperature differential between a first temperature sensor disposed at a first location of a cooling plate of the energy storage system thermal management circuit and a second temperature sensor disposed at a second location of the cooling plate of the energy storage system thermal management circuit, the multi-port valve assembly is switched between the following modes:
a first mode coupling the heat-cold source thermal management circuit to the energy storage system thermal management circuit with a first cooling plate port serving as an inlet and a second cooling plate port serving as an outlet; and
a second mode cross-coupling the heat-cold source thermal management circuit to the energy storage system thermal management circuit with the second cooling plate port serving as the inlet and the first cooling plate port serving as the outlet.

15. A non-transitory computer readable medium stored in a memory and executed by a processor to carry out thermal management method steps, comprising:
responsive to an operating state of the vehicle, selectively coupling or isolating a heat-cold source thermal management circuit of the vehicle, an energy storage system thermal management circuit of the vehicle, and a powertrain thermal management circuit of the vehicle to or from one another using a multi-port valve assembly coupled to the heat-cold source thermal management circuit, the energy storage system thermal management circuit, and the powertrain thermal management circuit.

16. The non-transitory computer-readable medium of claim 15, wherein the heat-cold source thermal management circuit comprises a heat source, a cold source, or a pump, or a combination thereof, adapted to affect a temperature within the heat-cold source thermal management circuit.

17. The non-transitory computer-readable medium of claim 15, wherein the energy storage system thermal management circuit comprises an energy storage system.

18. The non-transitory computer-readable medium of claim 15, wherein the powertrain thermal management circuit comprises power electronics, a degas bottle, a radiator, an on-board charger, a direct current-to-direct current converter, or a pump, or a combination thereof.

19. The non-transitory computer-readable medium of claim 15, wherein the multi-port valve assembly comprises a single six-port valve assembly comprising three inlet ports and three outlet ports.

20. The non-transitory computer-readable medium of claim 15, wherein, responsive to the operating state of the vehicle, the multi-port valve assembly is operated in one of the following modes:
a first mode coupling the heat-cold source thermal management circuit to the energy storage system thermal management circuit and isolating the powertrain thermal management circuit from the heat-cold source thermal management circuit and the energy storage system thermal management circuit;
a second mode cross-coupling the heat-cold source thermal management circuit to the energy storage system thermal management circuit and isolating the powertrain thermal management circuit from the heat-cold source thermal management circuit and the energy storage system thermal management circuit;
a third mode isolating the heat-cold source thermal management circuit, the energy storage system thermal management circuit, and the powertrain thermal management circuit from one another;
a fourth mode coupling the heat-cold source thermal management circuit to the powertrain thermal management circuit and isolating the energy storage system thermal management circuit from the heat-cold source thermal management circuit and the powertrain thermal management circuit; and
a fifth mode coupling the heat-cold source thermal management circuit, the energy storage system thermal management circuit, and the powertrain thermal management circuit to one another.
